(19) United States
(12) Patent Application Publication
(10) Pub. No.: US 2025/0140620 A1
(43) Pub. Date: May 1, 2025

(54) ELECTROSTATIC DISCHARGE DEVICES WITH METALLIZED DIES

(71) Applicant: TEXAS INSTRUMENTS INCORPORATED, Dallas, TX (US)

(72) Inventors: Thomas KRONENBERG, Dallas, TX (US); Mohammad WASEEM HUSSAIN, Irving, TX (US)

(21) Appl. No.: 18/498,679

(22) Filed: Oct. 31, 2023

(51) Int. Cl. H01L 23/31; H01L 21/56; H01L 21/683; H01L 23/00

(52) U.S. Cl. CPC H01L 23/3107; H01L 21/565; H01L 21/6836; H01L 24/48; H01L 2221/68327; H01L 2224/48465; H01L 2924/30205

(57) ABSTRACT

In examples, a method for manufacturing a package comprises depositing a metal contact layer on a surface of a wafer, the wafer including first and second diodes; positioning the wafer on an expandable tape coupled to a carrier; dicing the wafer to produce first and second dies, the first die including the first diode and the second die including the second diode; wire bonding the first die to the second die using a bond wire; covering the first and second dies and the bond wire with a mold compound to produce a molded structure; decoupling the molded structure from the expandable tape; and sawing the molded structure to produce the package.

### BACKGROUND

Semiconductor wafers are circular pieces of semiconductor material, such as silicon, that are used to manufacture semiconductor chips. Generally, complex manufacturing processes are used to form numerous integrated circuits on a single wafer. The formation of such circuits on a wafer is called fabrication. After wafer fabrication, the wafer is cut into multiple pieces, called semiconductor dies, with each die containing one of the circuits. The cutting, or sawing, of the wafer into individual dies is called singulation.

### SUMMARY

In examples, a method for manufacturing a package comprises depositing a metal contact layer on a surface of a wafer, the wafer including first and second diodes; positioning the wafer on an expandable tape coupled to a carrier; dicing the wafer to produce first and second dies, the first die including the first diode and the second die including the second diode; wire bonding the first die to the second die using a bond wire; covering the first and second dies and the bond wire with a mold compound to produce a molded structure; decoupling the molded structure from the expandable tape; and sawing the molded structure to produce the package.

In examples, a package comprises first and second dies including first and second diodes, respectively. The package also comprises first and second metal contacts coupled to bottom surfaces of the first and second dies, respectively, with the first and second metal contacts exposed to a bottom surface of the package and having thicknesses in the range of 1 um to 15 um. The package also comprises a bond wire coupled to top surfaces of the first and second dies, the top surfaces of the first and second dies opposing the bottom surfaces of the first and second dies. The package also includes a mold compound covering the first and second dies and the bond wire, the mold compound contacting the first and second metal contacts.

### BRIEF DESCRIPTION OF THE DRAWINGS

FIG. 1 is a block diagram of an electronic device including an electrostatic discharge device, in accordance with various examples.

FIG. 2 is a flow diagram of a method for manufacturing an electrostatic discharge device, in accordance with various examples.

FIGS. 3A1-3H3 are a process flow of a method for manufacturing an electrostatic discharge device, in accordance with various examples.

FIG. 4 is a flow diagram of a method for manufacturing an electrostatic discharge device, in accordance with various examples.

FIGS. 5A1-5E3 are a process flow of a method for manufacturing an electrostatic discharge device, in accordance with various examples.

### DETAILED DESCRIPTION

Various electronic devices, such as laptop and desktop computers, consumer electronics such as televisions, appliances, etc., are subject to occasional overvoltage conditions that represent a threat to the functional integrity of the devices. Overvoltage conditions, such as may be associated with a power surge, can damage electronic devices and render them unusable. For example, a dangerously high voltage may be provided to a pin within a universal serial bus (USB) port, potentially damaging the electronic device containing the port and/or any other devices that may be coupled to the port.

Some devices are useful to mitigate the risks that accompany overvoltage conditions. Generally, such devices contain dies that comprise diodes, and these dies are coupled to lead frame components (e.g., die pads). In addition, these devices contain die attach layers that couple the dies to the lead frame components. Consequently, the devices are undesirably large and expensive. These devices also sub-optimally dissipate heat and present high electrical resistance.

This disclosure describes various examples of electrostatic discharge devices (ESDs) that mitigate the technical challenges described above. Specifically, the ESDs include packages that omit lead frame components. Instead, the lead frame components are replaced with metal contacts that are applied by a deposition process, such as physical vapor deposition (PVD) or chemical vapor deposition (CVD). The metal contacts are applied at the wafer level. The use of deposition techniques eliminates the inclusion of lead frame components in these ESDs as well as the inclusion of die attach layers in the ESDs. By eliminating both lead frame components and die attach layers, the resulting ESDs are thinner, cost less to manufacture, provide better heat dissipation, and provide reduced electrical resistance. Thus, the ESDs described herein present a technical solution to numerous technical problems. Various examples of these ESDs are now described with reference to the drawings.

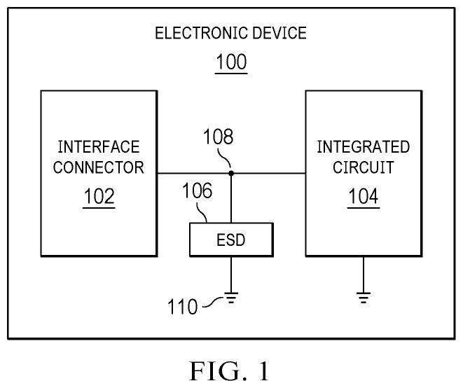

FIG. 1 is a block diagram of an electronic device 100 including an electrostatic discharge device (ESD), in accordance with various examples. The electronic device 100 may be any suitable type of device, such as a computer (e.g., a laptop computer, a desktop computer, a notebook computer), a consumer electronic device (e.g., a television, a stereo system), an appliance, a vehicle, an aircraft, a spacecraft, etc. The electronic device 100 includes an interface connector 102, such as a universal serial bus (USB) port, a high-definition multimedia interface (HDMI) port, etc. Other types of ports and connectors are contemplated and included in the scope of this disclosure. An integrated circuit (IC) 104 is coupled to the connector 102. For example, the IC 104 may include circuitry configured to perform one or more functions to enable or facilitate the operations of the electronic device 100. The connector 102 may couple to another device external to the electronic device 100, with a cable (e.g., USB or HDMI cable) facilitating communications between that external device and the IC 104, as well as with other circuitry and/or devices that may be coupled to the connector 102.

The electronic device 100 may include an ESD 106 coupled to the connector 102 and the IC 104. The connector 102, IC 104, and ESD 106 may be coupled to a common printed circuit board (PCB), in some examples. In other examples, one or more of the connector 102, IC 104, and ESD 106 may be coupled to different PCBs. The IC 104 may be coupled to specific pin(s) of the connector 102, and the ESD 106 may be coupled to at least those pin(s) to which the IC 104 is coupled. The ESD 106 is configured to protect the IC 104 from the consequences of overvoltage conditions. Specifically, when an overvoltage condition occurs, the voltage provided from the connector 102 to the IC 104 on node 108 may be beyond the voltage threshold that the IC 104 can safely tolerate. The ESD 106 is configured to close a circuit to ground 110 when the voltage on node 108 begins to approach this dangerous voltage threshold, but before the voltage threshold is actually reached. In this way, the voltage on node 108 is pulled to ground or close to ground, thus mitigating risk to the IC 104.

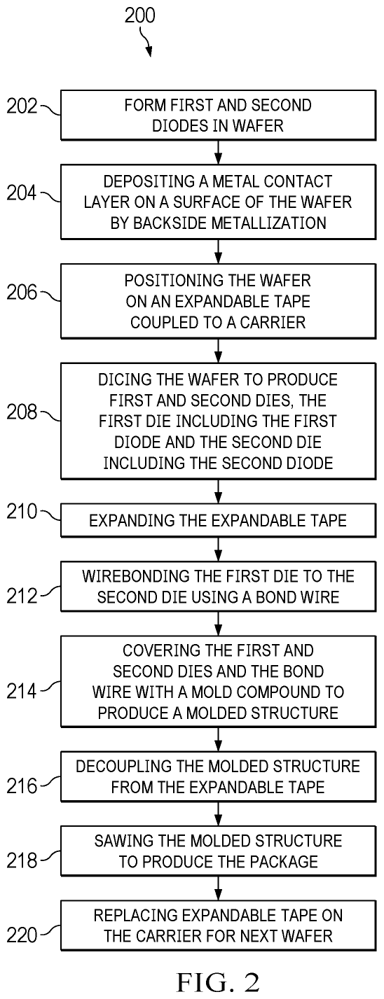

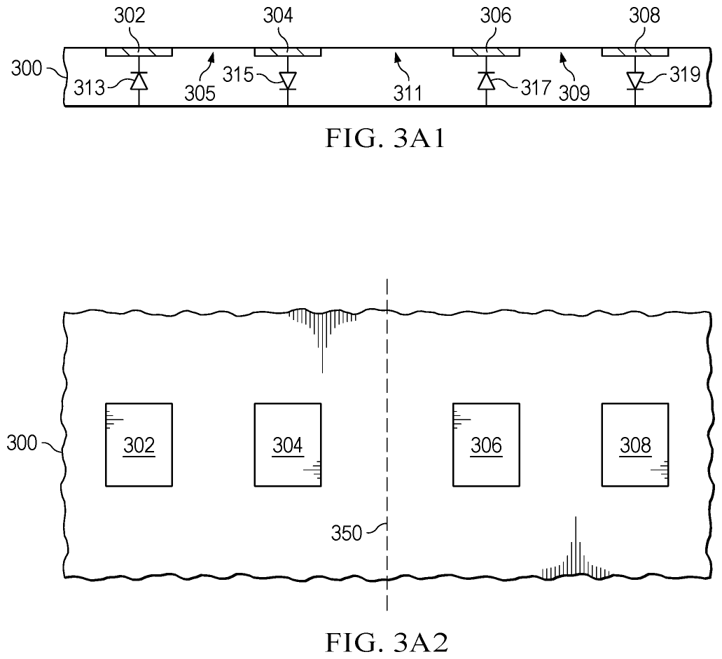

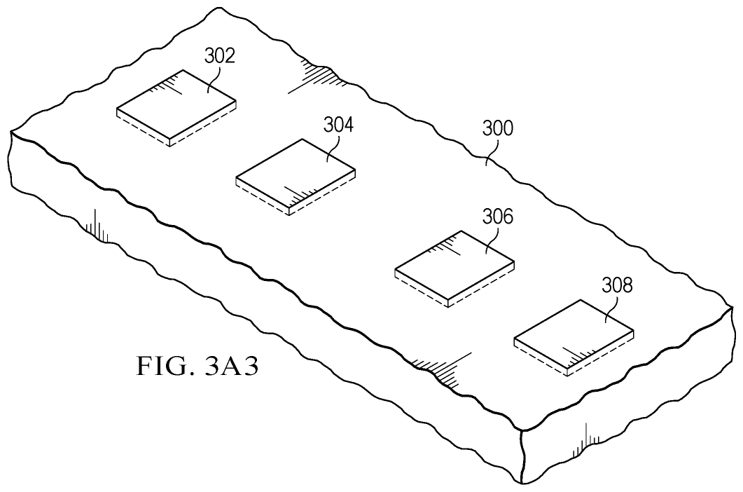

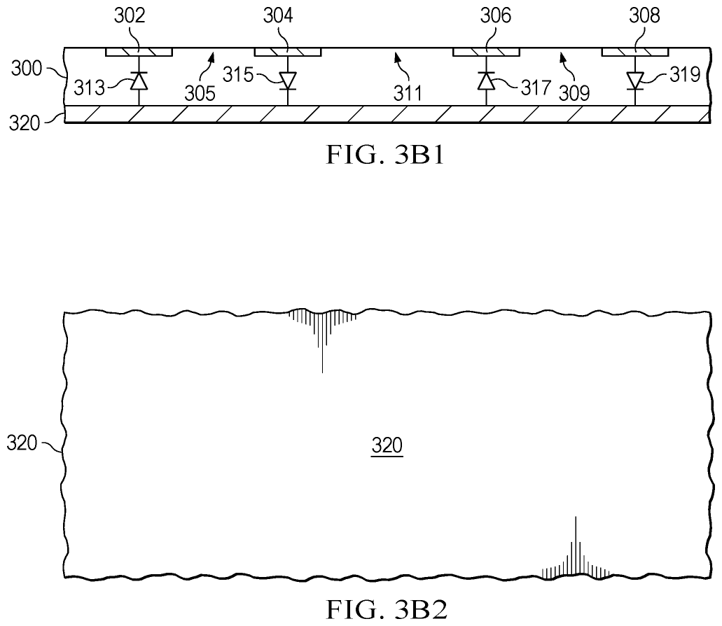

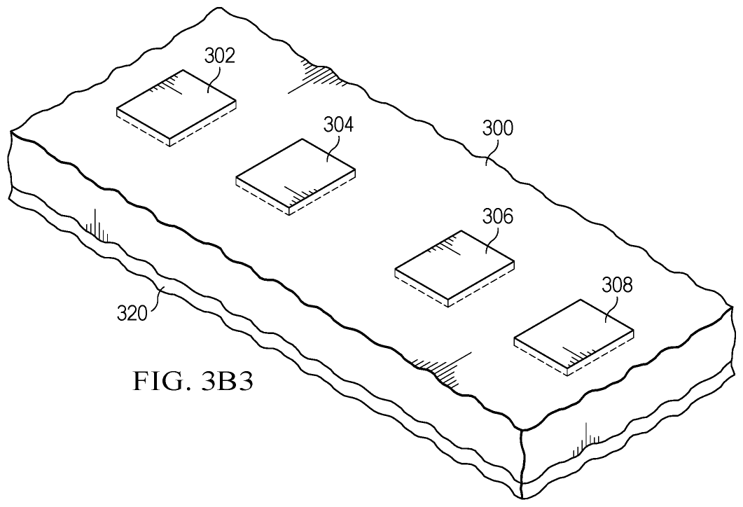

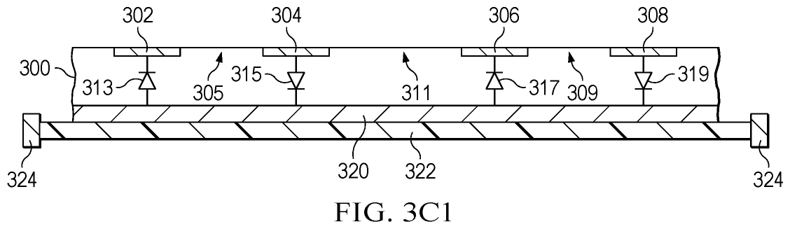

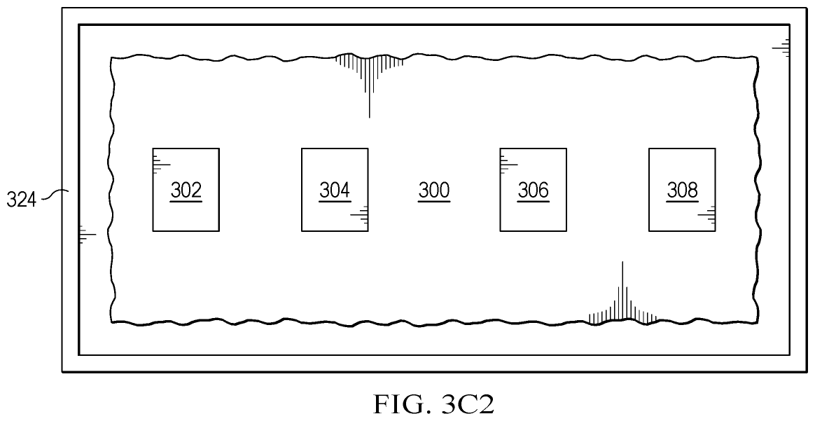

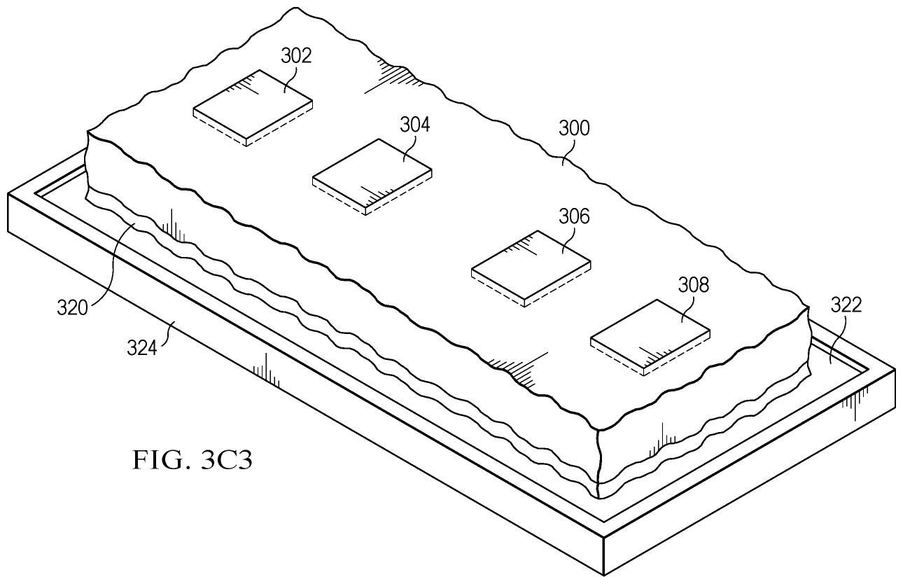

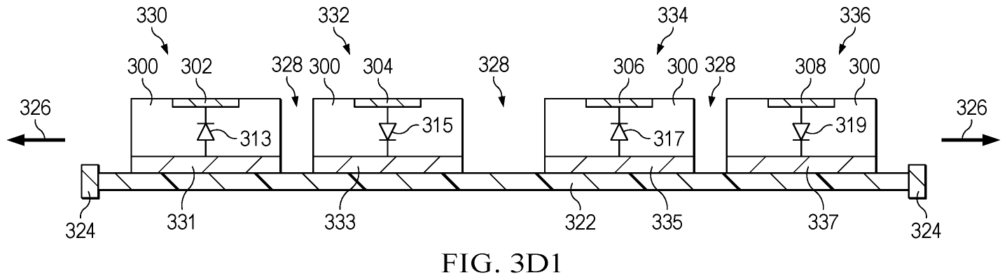

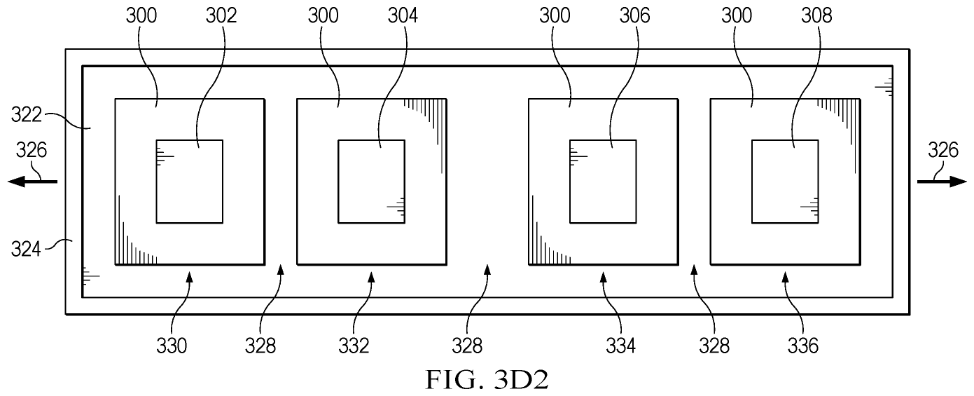

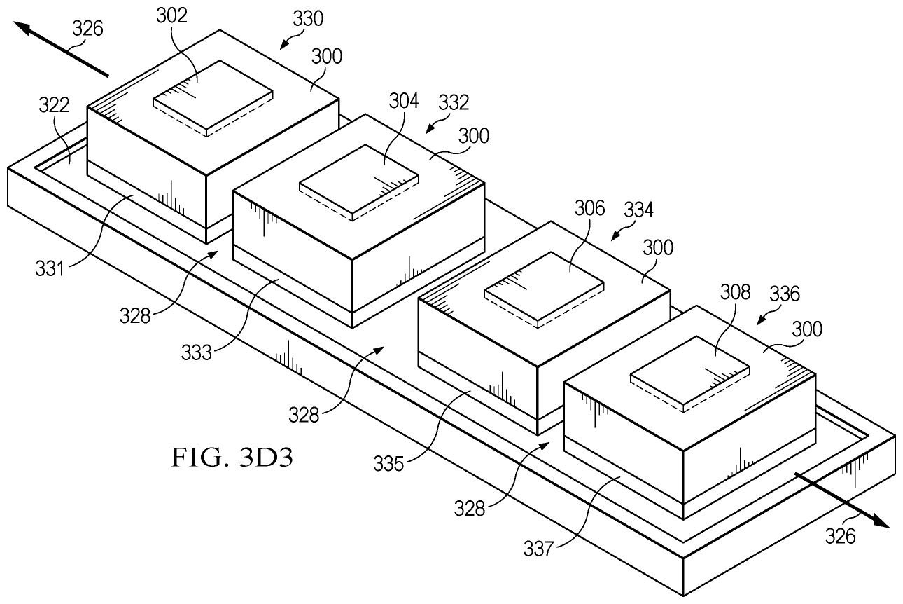

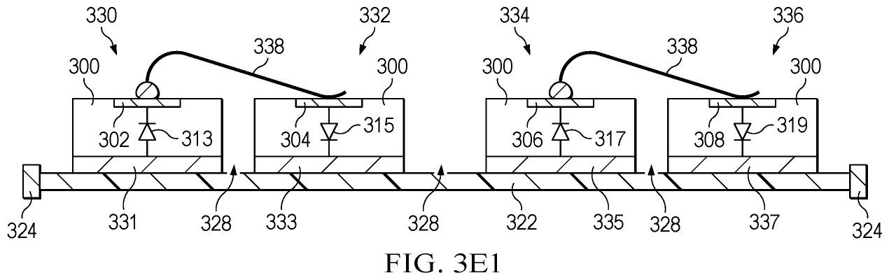

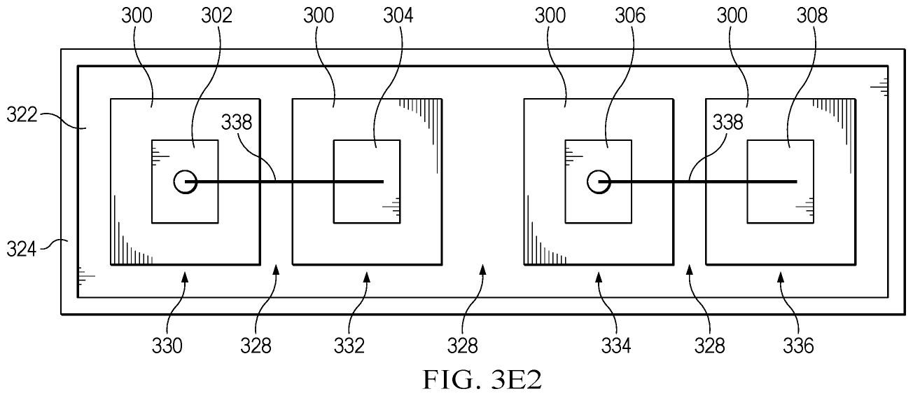

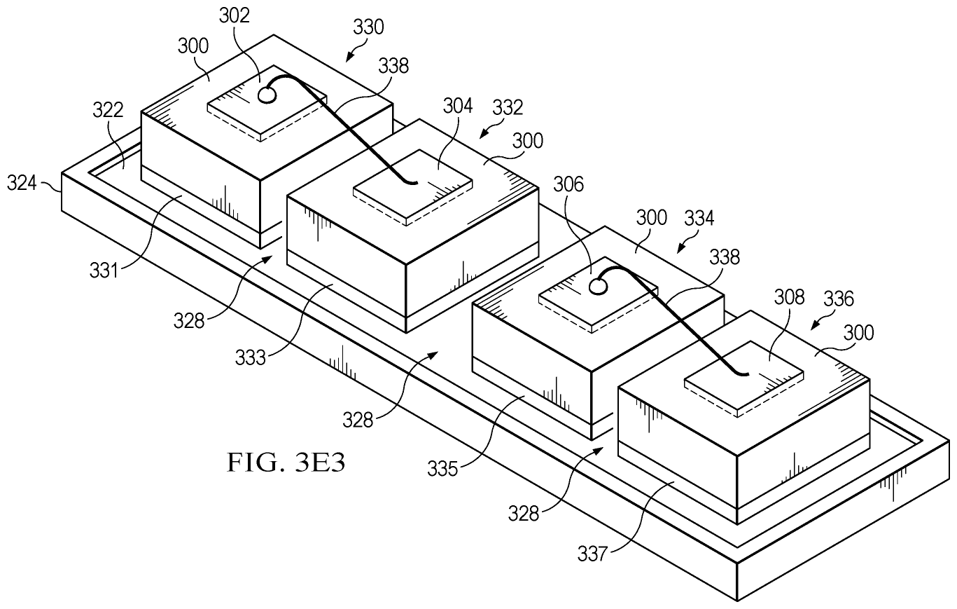

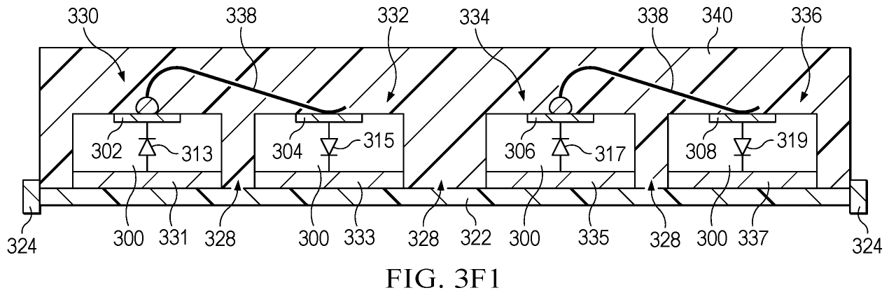

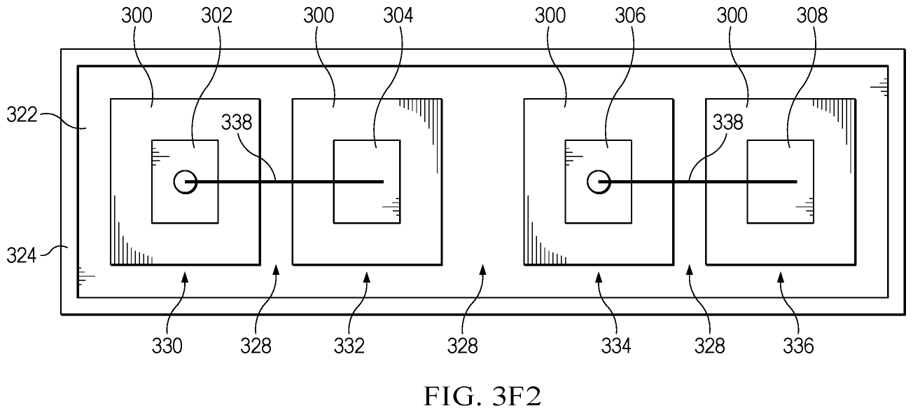

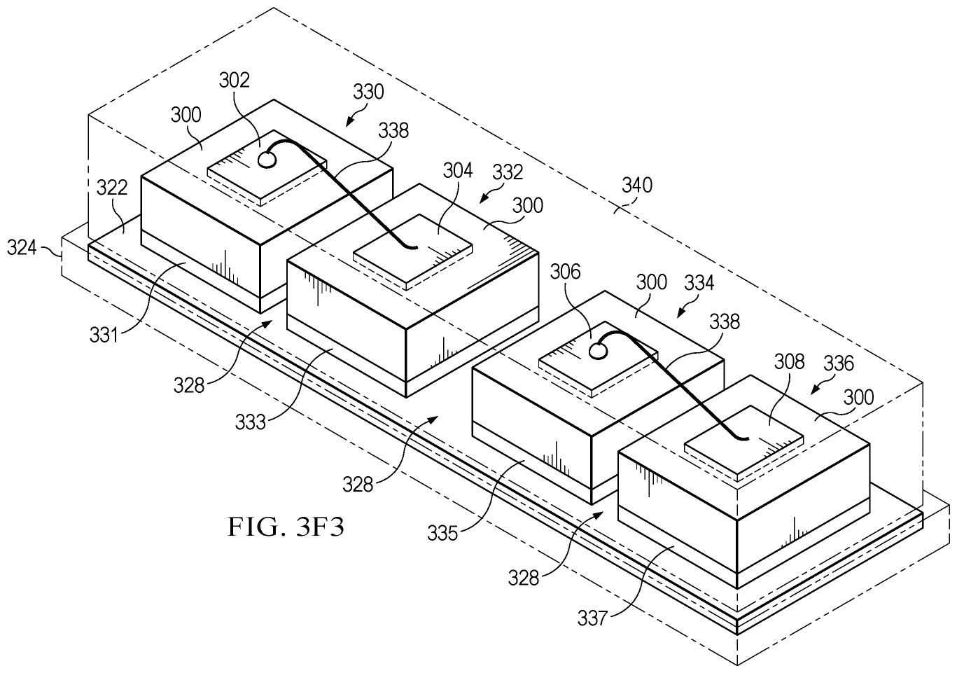

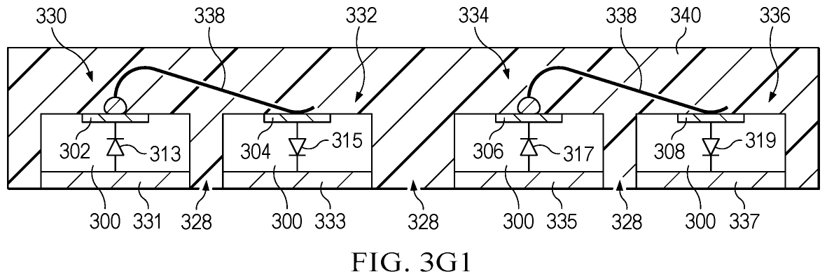

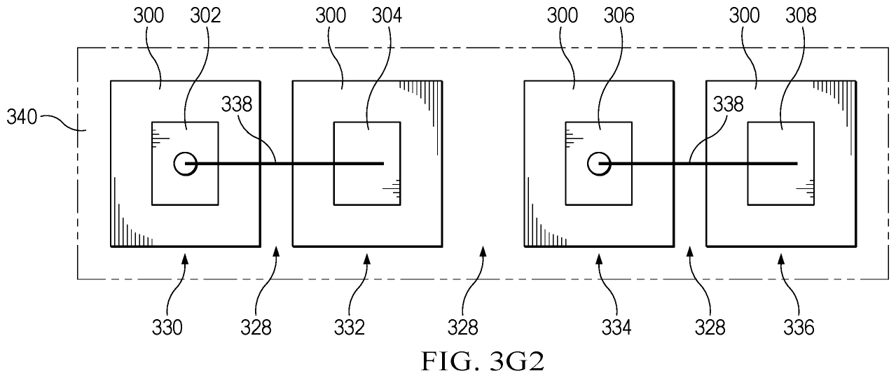

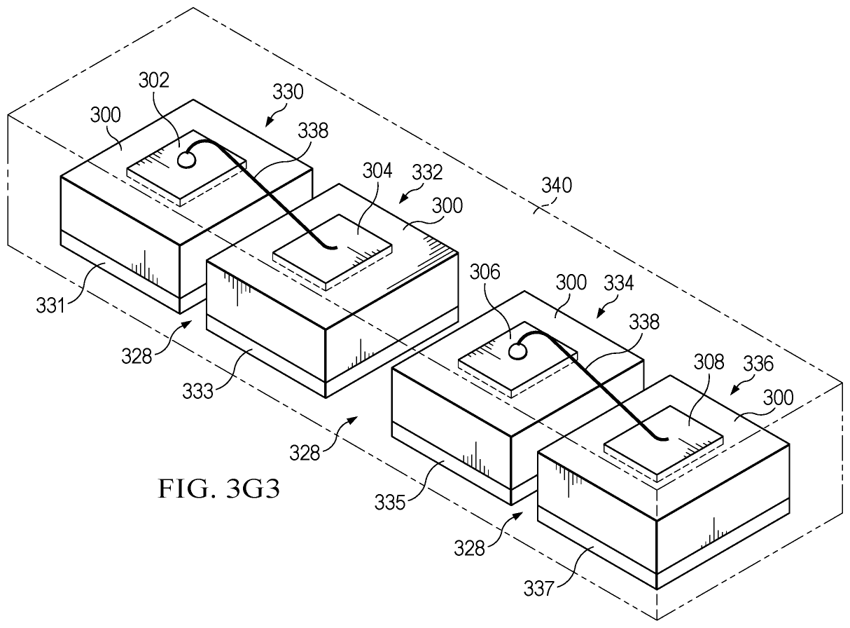

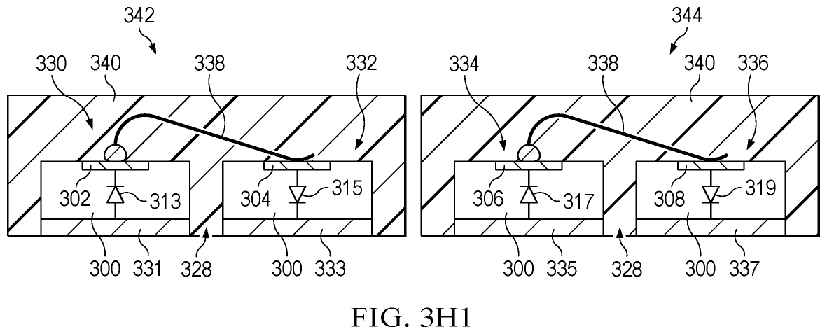

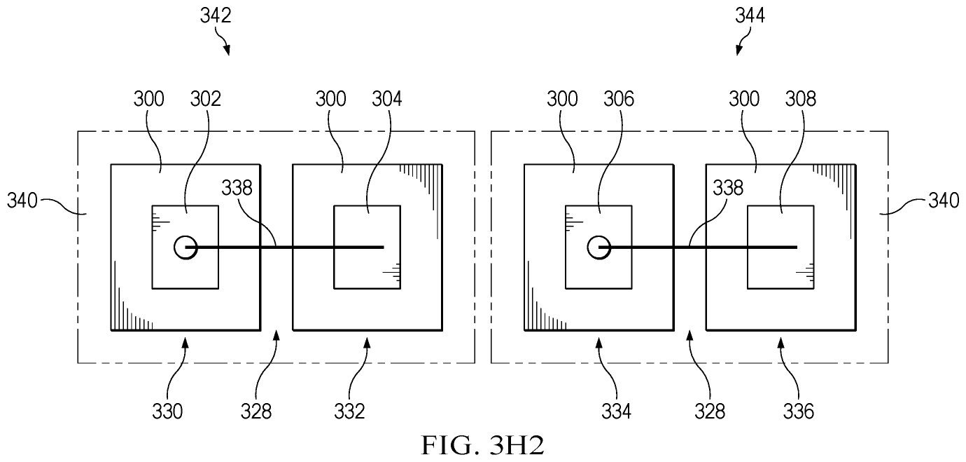

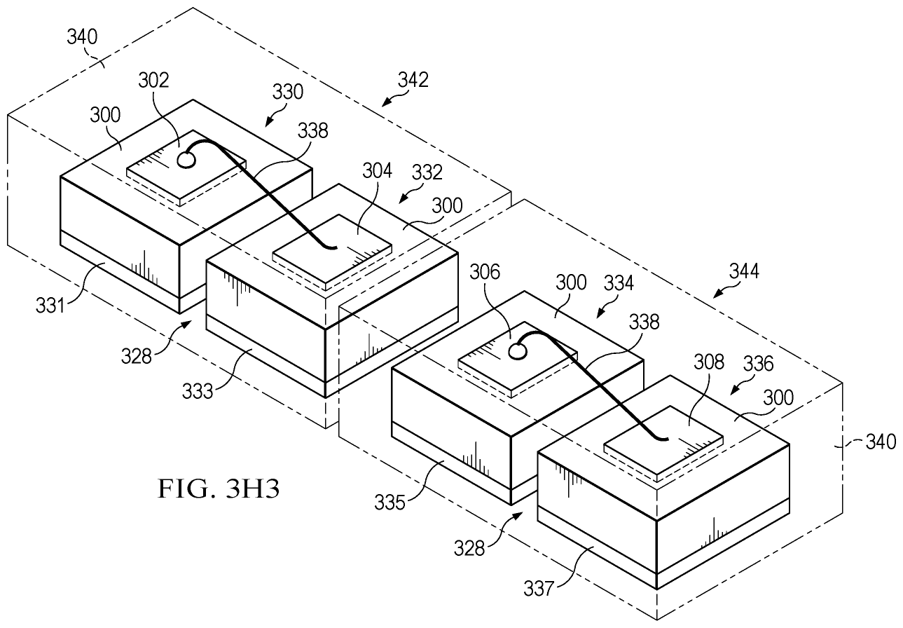

FIG. 2 is a flow diagram of a method 200 for manufacturing an electrostatic discharge device, such as the ESD 106 of FIG. 1, in accordance with various examples. FIGS. 3A1-3H3 are a process flow of the method 200 for manufacturing an electrostatic discharge device, such as the ESD 106, in accordance with various examples. Accordingly, FIGS. 2 and 3A1-3H3 are now described in parallel.

The method 200 includes forming first and second diodes in a semiconductor wafer (202). FIG. 3A1 is a profile, cross-sectional view of a wafer 300. Diodes 313, 315, 317, and 319 are formed within the wafer 300 and are coupled to metal contacts 302, 304, 306, and 308 (e.g., plated or deposited by metal evaporation deposition), respectively. Although the method 200 describes the formation of two diodes in the wafer, FIG. 3A1 shows four such diodes. The diodes are represented with diode symbols to better illustrate anode and cathode terminal orientations. The scope of this disclosure is not limited to any particular type of diode. A gap 305 separates the metal contacts 302 and 304. A gap 309 separates the metal contacts 306 and 308. A gap 311 separates the metal contacts 304 and 306. In examples, each of the diodes 313, 315, 317, and 319 has a threshold voltage (i.e., the voltage at which the diode closes circuit and allows current to pass through) that is a fraction of the total threshold voltage of the ESD 106. For example, the structure shown in FIG. 3A1 will later be singulated (e.g., sawn) vertically at gap 311 to form two separate ESDs 106, as described below. Thus, diodes 313 and 315 will be part of one ESD 106, and diodes 317 and 319 will be part of a different ESD 106. The threshold voltages of diodes 313 and 315 should combine to equal the desired threshold voltage for the ESD 106 in which they are included. Similarly, the threshold voltages of diodes 317 and 319 should combine to equal the desired threshold voltage for the ESD 106 in which they are included. For example, the diodes 313 and 315 may each have threshold voltages of 1.6 V for a total combined threshold voltage of the respective ESD 106 of 3.2 V. The diode 313 must be oriented (i.e., formed in the wafer 300) such that the cathode of the diode 313 is more proximal to the metal contact 302 and the anode of the diode 313 is more distal to the metal contact 302. The diode 315 must be oriented such that the anode of the diode 315 is more proximal to the metal contact 304 and the cathode of the diode 315 is more distal to the metal contact 304. The diode 317 must be oriented (i.e., formed in the wafer 300) such that the cathode of the diode 317 is more proximal to the metal contact 306 and the anode of the diode 317 is more distal to the metal contact 306. The diode 319 must be oriented such that the anode of the diode 319 is more proximal to the metal contact 308 and the cathode of the diode 319 is more distal to the metal contact 308. FIG. 3A2 is a top-down view of the structure of FIG. 3A1 in accordance with some examples, and FIG. 3A2 depicts a wafer saw street 350. FIG. 3A3 is a perspective view of the structure of FIG. 3A1 in accordance with some examples.

The method 200 includes depositing a metal contact layer on a surface of the wafer by backside metallization (BSM) (204). FIG. 3B1 is a profile, cross-sectional view of the structure of FIG. 3A1, but with a metal contact layer 320 contacting the backside of the wafer 300. The metal contact layer 320 may be applied to the wafer 300 by any suitable technique other than stamping, such as a metal deposition technique (e.g., physical vapor deposition (PVD), chemical vapor deposition (CVD), plating, etc.). However, the metal contact layer 320 is not part of a lead frame, nor was it formerly part of a lead frame. Stated another way, the metal contact layer 320 is not formed by stamping, but may be formed instead by a deposition technique, such as PVD, CVD, plating, etc. For example, the formation of the metal contact layer 320 may include a wafer preparation stage (e.g., cleaning, chemical treatments), a backside cleaning stage (e.g., to remove contaminants or particles), a possible barrier deposition stage (e.g., using titanium or titanium-tungsten or another suitable metal or alloy, to enhance adhesion and prevent metal diffusion into the semiconductor wafer), and deposition of the metal contact layer 320 using PVD, CVD, plating, etc. Optionally, additional steps such as patterning and etching, final cleaning, etc., may be performed, depending on the specific application. Unlike die attach pads, which are not electrically conductive, the metal contact layer 320 is composed of metal, which is thermally and electrically conductive. In addition, die attach pads couple to wafers or dies by way of a die attach layer or film, which have specific properties that affect thermal and electrical conductivity and other properties, and in examples the metal contact layer 320 does not couple to the wafer or die 300 by way of such a die attach layer or film. Because the metal contact layer 320 is applied by deposition instead of coupling to a lead frame component, no die attach layer is necessary, and thus die attach layers are omitted from the completed packages described herein.

The metal contact layer 320, as well as the metal contacts formed by cutting the metal contact layer 320 as described below (i.e., metal contacts 331, 333, 335, 337), have certain physical properties that evidence the use of a deposition technique instead of a stamping technique as would be the case with a lead frame. For example, metals deposited by chemical vapor deposition typically have a dense and conformal microstructure. The metal atoms are deposited from gas-phase precursors and result in uniform coverage over the structure on which the metal is deposited. Metals deposited by CVD tend to have relatively increased thickness uniformity and minimal impurities. Metals deposited by physical vapor deposition (PVD) have a columnar microstructure, with elongated grains aligned perpendicular to the substrate on which the metal is deposited. The microstructure is a result of the physical processes that may be involved, such as sputtering and evaporation. The crystallographic orientation of PVD-deposited metals is influenced by deposition conditions. PVD films also have minimal impurities. In contrast to CVD and PVD, stamped metals tend to have a polycrystalline structure with grains that are randomly oriented. The thickness and uniformity of stamped metals depend on the stamping process and can vary, with variations in thickness, especially on intricate or contoured surfaces.

The thickness of the metal contact layer 320 ranges from 1 micron (um) to 15 um, with a thickness below this range being disadvantageous because of poor solderability, and with a thickness above this range being disadvantageous because of unacceptable plating and cost inefficiencies. In examples, the metal contact layer 320 covers the entire surface of the wafer 300, as shown. In other examples, the metal contact layer 320 may be selectively formed by combining an appropriate metal deposition technique (e.g., PVD, CVD) with a patterned mask or masks to produce one or more gaps in the metal contact layer 320, with such a gap(s) being in vertical alignment with future sawing locations on the wafer 300 (e.g., in between each of the diodes shown in FIG. 3A1). FIG. 3B2 is a bottom-up view of the structure of FIG. 3B1, in accordance with various examples. FIG. 3B3 is a perspective view of the structure of FIG. 3B1, in accordance with various examples.

The method 200 includes positioning the wafer on an expandable tape coupled to a carrier (206). FIG. 3C1 is a profile, cross-sectional view of the structure of FIG. 3B1, except that the structure of FIG. 3B1 has been mounted on an expandable tape 322 coupled to a frame (e.g., flex frame), or more generally, a carrier 324. In the drawings, the carrier 324 is shown as rectangular and reduced in size because only a representative portion of the wafer 300 is shown in FIG. 3A1 et seq., but in practice, the carrier 324 and the expandable tape 322 may be different shapes (e.g., circular) and/or sizes. The expandable tape 322 may be of any suitable type, such as polyimide films with adhesive. The carrier 324 may be any suitable type of carrier, such as stainless steel. FIG. 3C2 is a top-down view of the structure of FIG. 3C1, in accordance with various examples. FIG. 3C3 is a perspective view of the structure of FIG. 3C1, in accordance with various examples.

The method 200 includes dicing the wafer to produce first and second dies, with the first die including the first diode and the second die including the second diode (208). FIG. 3D1 is a profile, cross-sectional view of the structure of FIG. 3C1, except that the wafer 300 has been diced into multiple dies 330, 332, 334, and 336, with gaps 328 separating these dies from each other. Each of the dies 330, 332, 334, and 336 includes a metal contact 331, 333, 335, and 337 formed from the metal contact layer 320, respectively. As explained above, the metal contact layer 320 (and thus, the metal contacts 331, 333, 335, and 337) is and was not part of a lead frame and was not formed by stamping, but rather by a suitable deposition process. The thickness of each of the metal contacts 331, 333, 335, and 337 ranges from 1 um to 15 um, with a thickness below this range being disadvantageous because of poor solderability, and with a thickness above this range being disadvantageous because of unacceptable plating and cost inefficiencies. The gaps 328 extend through the thickness of the formerly intact wafer 300 and through the thickness of the formerly intact metal contact layer 320, such that the gaps 328 extend down to the expandable tape 322, as shown. Any suitable dicing technique may be useful to form the gaps 328. For example, a saw may be useful to cut through the wafer 300 and the metal contact layer 320. In other examples, an etch may be useful to etch through the wafer 300, and a saw (e.g., mechanical, laser, etc.) may be useful to cut through the metal contact layer 320. In other examples, an etch may be useful to etch through the wafer 300 and the metal contact layer 320.

The method 200 includes expanding the expandable tape so as to further separate the dies 330, 332, 334, and 336 from each other, for example by expanding the gaps 328 (210). In FIG. 3D1, arrows 326 indicate a force applied to expand the extendable tape 322, as shown. The expandable tape 322 must be expanded such that the widths of the gaps 328 are between 100 um and 300 um, with gap widths below this range being disadvantageous because of PCB solder bridging, and with gap widths above this range being disadvantageous because it unacceptably increases the size of the package. FIG. 3D2 is a top-down view of the structure of FIG. 3D1, in accordance with various examples. FIG. 3D3 is a perspective view of the structure of FIG. 3D1, in accordance with various examples. The length and width of each die 330, 332, 334, and 336 are between 100 um and 1000 um, with sizes below this range being disadvantageous because of solderability and die handling challenges, and with die sizes above this range being disadvantageous because it unacceptably grows the size and cost of the solution for target applications.

The method 200 includes wire bonding the first die to the second die using a bond wire (212). FIG. 3E1 is a profile, cross-sectional view of the structure of FIG. 3D1, except with the addition of bond wires 338. A first bond wire 338 couples the dies 330, 332 together, and more specifically, couples the metal contacts 302, 304 together. A second bond wire 338 couples the dies 334, 336 together, and more specifically, couples the metal contacts 306, 308 together. Any suitable wire bonding technique may be useful, such as ball bonds, stitch bonds, etc. FIG. 3E2 is a top-down view of the structure of FIG. 3E1, in accordance with various examples. FIG. 3E3 is a perspective view of the structure of FIG. 3E1, in accordance with various examples.

The method 200 includes covering the first and second dies and the bond wire with a mold compound to produce a molded structure (214). FIG. 3F1 is a profile, cross-sectional view of the structure of FIG. 3E1, except that a mold compound 340 has been applied to the structure, as shown. The mold compound 340 may be applied using any suitable technique, such as mold injection techniques, for example. The metal contacts 331, 333, 335, and 337 must be exposed to a bottom surface of the mold compound 340, meaning that the metal contacts 331, 333, 335, and 337 are accessible from the bottom surface of the mold compound 340. FIG. 3F2 is a top-down view of the structure of FIG. 3F1, in accordance with various examples. FIG. 3F3 is a perspective view of the structure of FIG. 3F1, in accordance with various examples.

The method 200 comprises decoupling the molded structure from the expandable tape and carrier (216). FIG. 3G1 is a profile, cross-sectional view of the structure of FIG. 3F1, except that the expandable tape 322 and carrier 324 have been removed from the molded structure. FIG. 3G2 is a top-down view of the structure of FIG. 3G1, in accordance with various examples. FIG. 3G3 is a perspective view of the structure of FIG. 3G1, in accordance with various examples.

The method 200 comprises sawing the molded structure to produce individual packages (218). FIG. 3H1 is a profile, cross-sectional view of the structure of FIG. 3G1, except that the molded structure has been sawn to produce individual packages 342, 344. In examples, the sawing is performed between the dies 332 and 334. The completed packages 342, 344 each lack a die attach layer, as described above. FIG. 3H2 is a top-down view of the structure of FIG. 3H1, in accordance with various examples. FIG. 3H3 is a perspective view of the structure of FIG. 3H1, in accordance with various examples. The expandable tape 322 on the carrier 324 may be removed from the carrier 324 and replaced to prepare for the next wafer, meaning that the carrier 324 is reusable in this context (220).

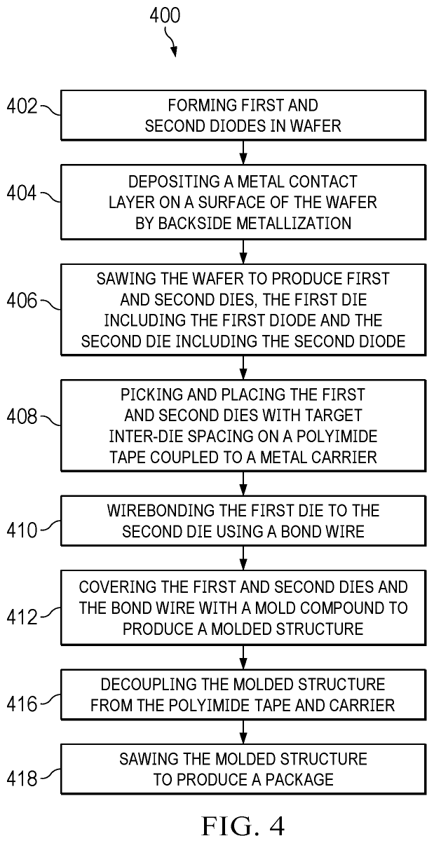

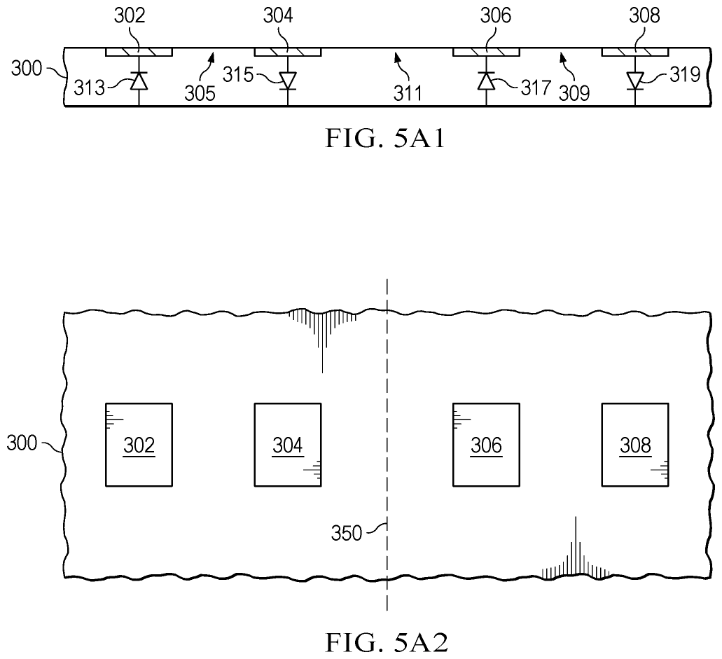

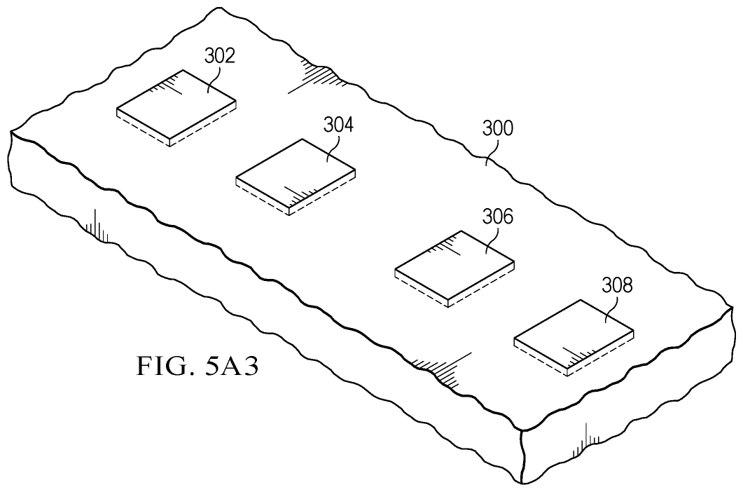

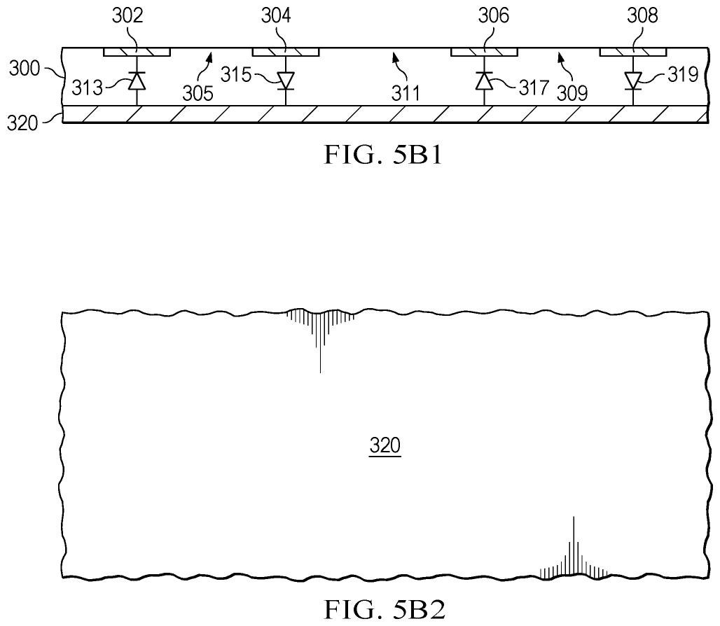

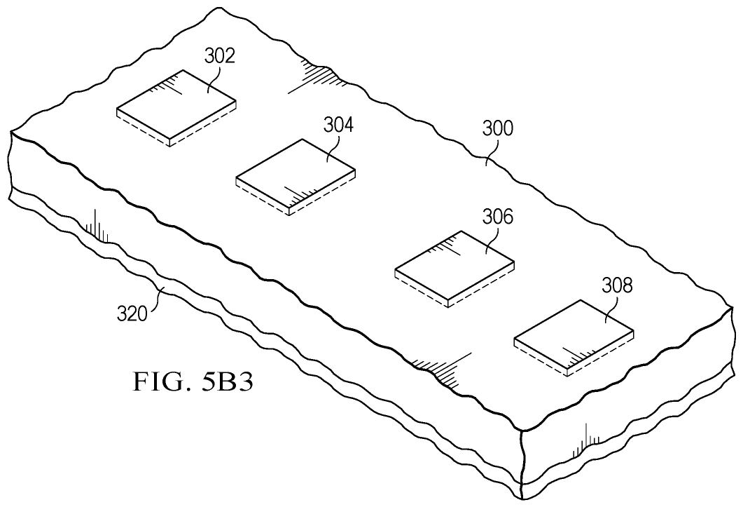

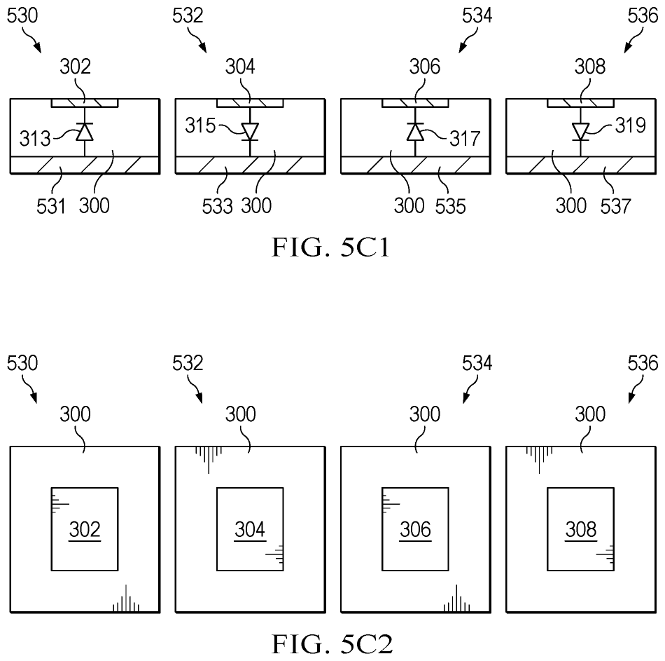

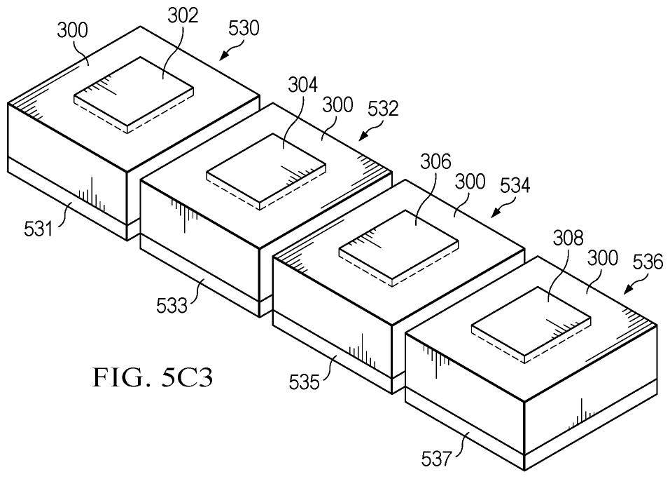

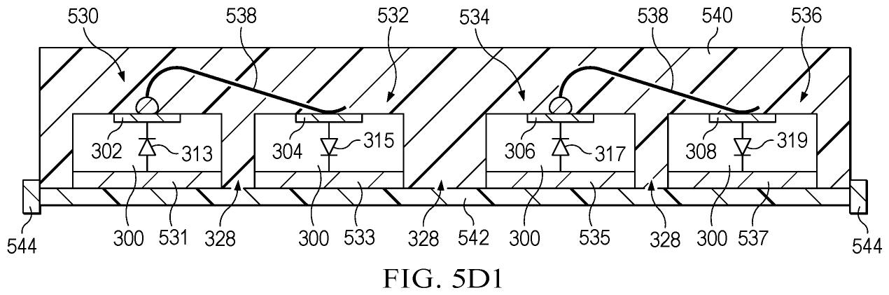

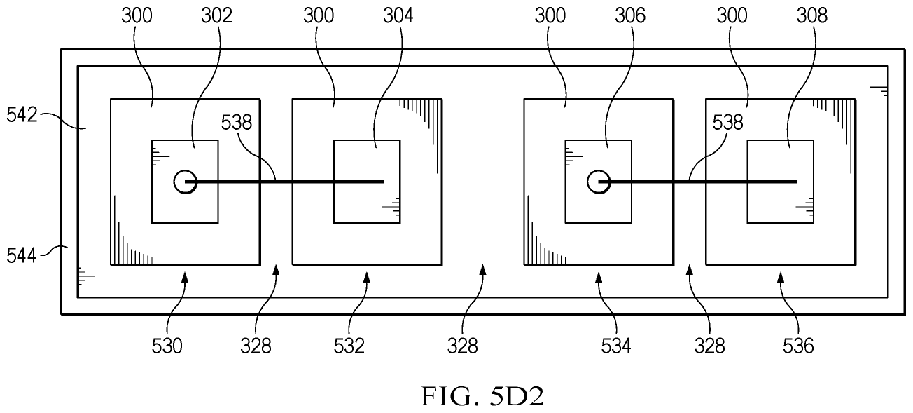

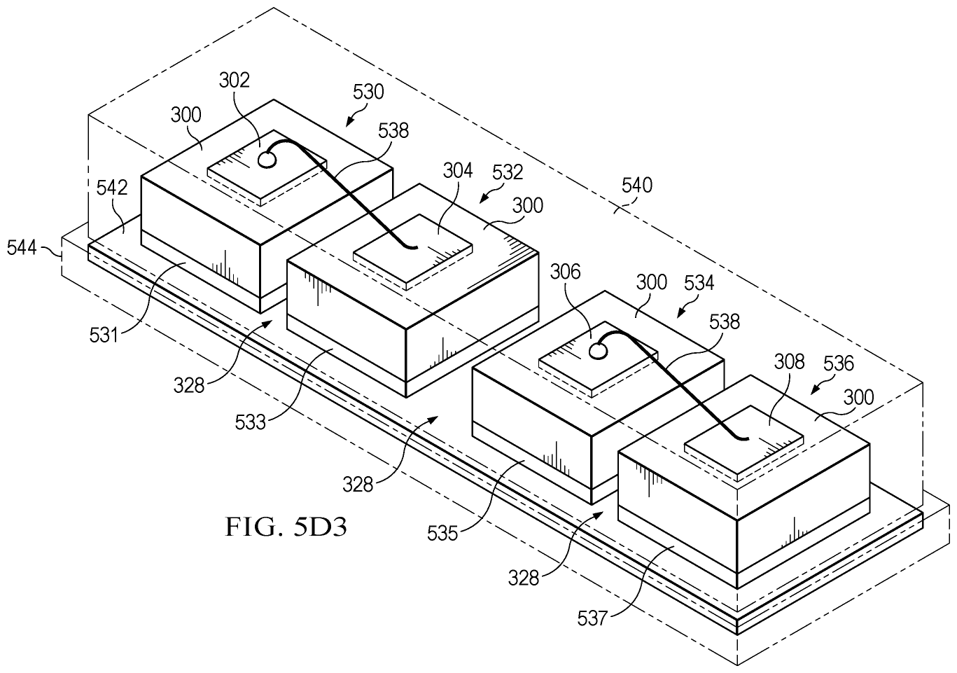

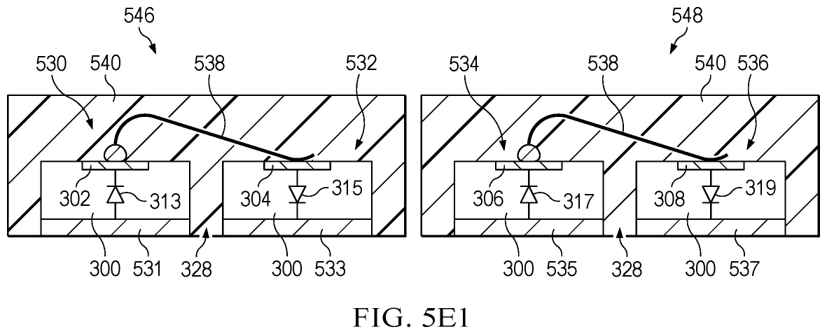

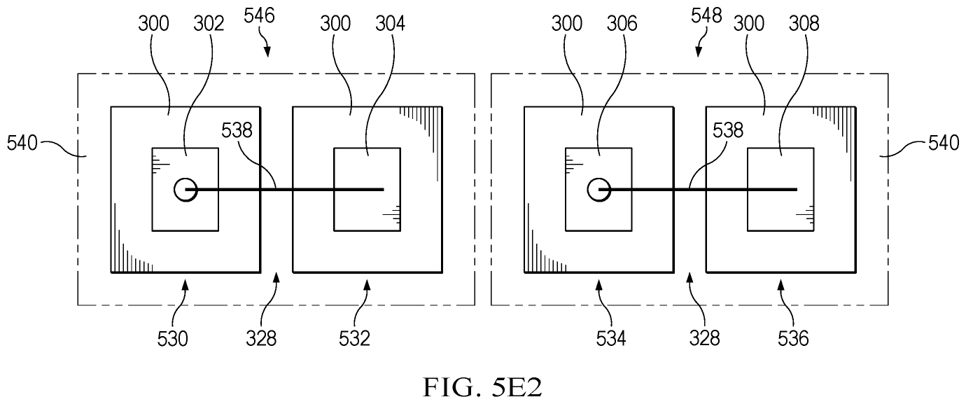

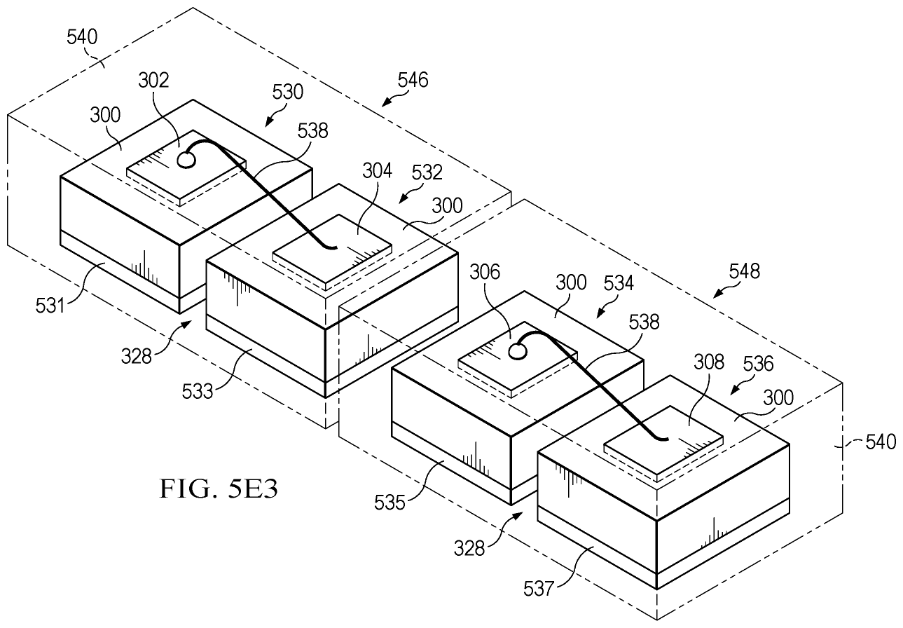

FIG. 4 is a flow diagram of a method 400 for manufacturing an electrostatic discharge device, in accordance with various examples. FIGS. 5A1-5E3 are a process flow of a method for manufacturing an electrostatic discharge device, in accordance with various examples. Thus, FIGS. 4 and 5A1-5E3 are now described in parallel.

The method 400 includes forming first and second diodes in a semiconductor wafer (402). FIG. 5A1 is a profile, cross-sectional view of such a wafer. The structure of FIG. 5A1 is identical to that of FIG. 3A1, and thus the description of FIG. 3A1 provided above applies equally to FIG. 5A1 and is not repeated here. FIG. 5A2 is a top-down view of the structure of FIG. 5A1, in accordance with various examples. FIG. 5A3 is a perspective view of the structure of FIG. 5A1, in accordance with various examples.

The method 400 includes depositing a metal contact layer on a surface of the wafer by backside metallization (404). FIG. 5B1 is a profile, cross-sectional view of such a wafer having a backside metallization, in accordance with various examples. The structure of FIG. 5B1 is identical to that of FIG. 3B1, and thus the description of FIG. 3B1 provided above applies equally to FIG. 5B1 and is not repeated here. FIG. 5B2 is a top-down view of the structure of FIG. 5B1, in accordance with various examples. FIG. 5B3 is a perspective view of the structure of FIG. 5B1, in accordance with various examples.

The method 400 includes sawing the wafer to produce first and second dies, with the first die including the first diode and the second die including the second diode (406). FIG. 5C1 is a profile, cross-sectional view of the wafer of FIG. 5B1 having been sawn to produce individual dies 530, 532, 534, and 536 having metal contacts 531, 533, 535, and 537, respectively. The physical properties of the metal contacts 531, 533, 535, and 537 are identical to those of the metal contacts 331, 333, 335, and 337, respectively, and thus are not repeated here. FIG. 5C2 is a top-down view of the structure of FIG. 5C1, in accordance with various examples. FIG. 5C3 is a perspective view of the structure of FIG. 5C1, in accordance with various examples.

The method 400 includes picking and placing the first and second dies with target inter-die spacing on a polyimide tape coupled to a metal carrier (408). The method 400 includes wire bonding the first die to the second die using a bond wire (410). The method 400 includes covering the first and second dies and the bond wire with a mold compound to produce a molded structure (412). FIG. 5D1 is a profile, cross-sectional view of the dies 530, 532, 534, and 536 positioned on a polyimide tape 542 coupled to a metal carrier 544. The dies 530, 532, 534, and 536 are spaced as desired using the pick-and-place technique (e.g., die reconstitution technique)-in some examples, the inter-die spacing is selected to be compatible with specific manufacturing tooling and equipment (e.g., wire bonding equipment) to realize manufacturing efficiencies and cost efficiencies. The dies 530 and 532 are coupled by a bond wire 538, and the dies 534 and 536 are coupled by another bond wire 538. A mold compound 540 covers the various structures shown in FIG. 5D1. FIG. 5D2 is a top-down view of the structure of FIG. 5D1, in accordance with various examples. FIG. 5D3 is a perspective view of the structure of FIG. 5D1, in accordance with various examples.

The method 400 includes decoupling the molded structure from the polyimide tape and carrier (416) and sawing the molded structure to produce a package (418). FIG. 5E1 is a profile, cross-sectional view of the completed packages 546, 548 after singulation and decoupling from the polyimide tape and carrier, in accordance with various examples. The structures of the packages 546, 548 are identical to those of the packages 342, 344, respectively, and thus the description provided above for the packages 342, 344 applies equally to packages 546, 548, respectively, and is not repeated here. FIG. 5E2 is a top-down view of the structure of FIG. 5E1, in accordance with various examples. FIG. 5E3 is a perspective view of the structure of FIG. 5E1, in accordance with various examples.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

In this description, unless otherwise stated, “about,” “approximately” or “substantially” preceding a parameter means being within +/−10 percent of that parameter. Modifications are possible in the described examples, and other examples are possible within the scope of the claims.

What is claimed is:

1. A method for manufacturing a package, comprising:
depositing a metal contact layer on a surface of a wafer, the wafer including first and second diodes;
positioning the wafer on an expandable tape coupled to a carrier;
dicing the wafer to produce first and second dies, the first die including the first diode and the second die including the second diode;
wire bonding the first die to the second die using a bond wire;
covering the first and second dies and the bond wire with a mold compound to produce a molded structure;
decoupling the molded structure from the expandable tape; and
sawing the molded structure to produce the package.

2. The method of claim 1, wherein positioning the wafer on the expandable tape includes contacting the metal contact layer to the expandable tape.

3. The method of claim 1, further comprising separating the first and second dies using the expandable tape.

4. The method of claim 1, wherein wirebonding the first die to the second die includes wirebonding a first surface of the first die to a second surface of the second die, the first and second surfaces opposing the surface of the wafer on which the metal contact layer is deposited.

5. The method of claim 1, wherein the metal contact layer has a thickness ranging from 1 um to 15 um.

6. The method of claim 1, wherein the first die has a first metal contact coupled thereto and the second die has a second metal contact coupled thereto, the first and second metal contacts formed from the metal contact layer.

7. The method of claim 1, wherein the first die has a length and width between 100 um and 1000 um.

8. The method of claim 1, wherein depositing the metal contact layer comprises using physical vapor deposition (PVD).

9. The method of claim 1, wherein depositing the metal contact layer comprises using chemical vapor deposition (CVD).

10. A package, comprising:
first and second dies including first and second diodes, respectively;
first and second metal contacts coupled to bottom surfaces of the first and second dies, respectively, the first and second metal contacts exposed to a bottom surface of the package and having thicknesses in the range of 1 um to 15 um;
a bond wire coupled to top surfaces of the first and second dies, the top surfaces of the first and second dies opposing the bottom surfaces of the first and second dies; and
a mold compound covering the first and second dies and the bond wire, the mold compound contacting the first and second metal contacts.

11. The package of claim 10, wherein the first and second metal contacts are not part of a lead frame.

12. The package of claim 10, wherein the first and second metal contacts are applied to the bottom surfaces of the first and second dies by a metal deposition technique.

13. The package of claim 12, wherein the metal deposition technique is physical vapor deposition (PVD) or chemical vapor deposition (CVD).

14. The package of claim 10, wherein the package lacks a die attach layer.

15. The package of claim 10, wherein the first die has a length and width between 100 um and 1000 um.

16. A package, comprising:
first and second dies including first and second diodes, respectively;
first and second metal contacts coupled to bottom surfaces of the first and second dies, respectively, the first and second metal contacts exposed to a bottom surface of the package and having thicknesses in the range of 1 um to 15 um, wherein the first and second metal contacts have physical properties indicating that the first and second metal contacts were formed by deposition on the bottom surfaces of the first and second dies;
a bond wire coupled to top surfaces of the first and second dies, the top surfaces of the first and second dies opposing the bottom surfaces of the first and second dies; and
a mold compound covering the first and second dies and the bond wire, the mold compound contacting the first and second metal contacts,
wherein the package lacks a conductive die attach layer.

17. The package of claim 16, wherein the first and second metal contacts are not obtained from a lead frame.

18. The package of claim 16, wherein the first and second metal contacts are formed by physical vapor deposition (PVD).

19. The package of claim 16, wherein the first and second metal contacts are formed by chemical vapor deposition (CVD).

20. The package of claim 16, wherein the first die has a length and width between 100 um and 1000 um.

21. The package of claim 16, wherein the package is an electrostatic discharge device (ESD).
